(19) United States
(12) Patent Application Publication
(10) Pub. No.: US 2025/0113640 A1
(43) Pub. Date: Apr. 3, 2025

(54) DEVICE, APPARATUS, AND MOVING BODY

(71) Applicant: CANON KABUSHIKI KAISHA, Tokyo (JP)

(72) Inventors: DAIKI SHIRAHIGE, Kanagawa (JP); KAZUHIRO MORIMOTO, Kanagawa (JP)

(21) Appl. No.: 18/898,136

(22) Filed: Sep. 26, 2024

(30) Foreign Application Priority Data
Sep. 28, 2023 (JP) 2023-168618

(51) Int. Cl. H01L 27/146

(52) U.S. Cl. CPC H10F 39/806; H10F 39/182; H10F 39/199; H10F 39/8067; H10F 39/811

(57) ABSTRACT

A device according to an aspect of the present disclosure includes a plurality of pixels each including an avalanche photodiode. The plurality of pixels includes a first pixel, and a second pixel configured to photoelectrically convert incident light including light with a wavelength shorter than a wavelength of incident light to be photoelectrically converted by the first pixel. The first pixel is provided with a diffractive region configured to diffract incident light and the second pixel is not provided with the diffractive region.

### BACKGROUND

### Technical Field

The aspect of the embodiments relates to a device, an apparatus, and a moving body.

### Description of the Related Art

A photoelectric conversion device capable of detecting weak light at a single photon level by using avalanche multiplication is known. The specification of United States Patent Application Publication No. 2017/0186798 discusses a photoelectric conversion device having a configuration in which a sensor chip including an array of a plurality of pixels and a circuit chip on which a circuit for performing signal processing is formed are stacked and electrically connected to each other.

In the sensor chip of the photoelectric conversion device, an avalanche photodiode in which electric charges cause the avalanche multiplication is used for each pixel.

To improve sensitivity to incident light, a diffractive region may be formed in a semiconductor layer of a pixel using the avalanche photodiode. Formation of the diffractive region causes an optical path length of incident light in the semiconductor layer to increase, which leads to an improvement in sensitivity of the pixel.

As a result of study, however, it has been found that the diffractive region has a limited effect of sensitivity improvement in each pixel for photoelectrically converting visible light because the penetration length of visible light of a certain color with a wavelength shorter than infrared light into silicon forming the semiconductor layer is short.

Further, when the diffractive region is formed in the semiconductor layer, a dark current increases as the interface between the semiconductor layer and another layer increases, which may have an adverse effect on the performance of the photoelectric conversion device.

### SUMMARY

According to an aspect of the embodiments, a device includes a plurality of pixels each including an avalanche photodiode, in which the plurality of pixels includes a first pixel, and a second pixel configured to photoelectrically convert incident light including light with a wavelength shorter than a wavelength of incident light to be photoelectrically converted by the first pixel. The first pixel is provided with a diffractive region to diffract incident light, and the second pixel is not provided with the diffractive region.

Further features of the disclosure will become apparent from the following description of exemplary embodiments with reference to the attached drawings.

### BRIEF DESCRIPTION OF THE DRAWINGS

FIG. 1 is a schematic view of a photoelectric conversion device according to an exemplary embodiment.

FIG. 2 is a schematic diagram illustrating a pixel substrate of the photoelectric conversion device according to the exemplary embodiment.

FIG. 3 is a circuit diagram illustrating a circuit substrate of the photoelectric conversion device according to the exemplary embodiment.

FIG. 4 is a circuit diagram illustrating a configuration example of a pixel circuit of the photoelectric conversion device according to the exemplary embodiment.

FIGS. 5A and 5B schematically illustrate a driving operation of the pixel circuit of the photoelectric conversion device according to the exemplary embodiment.

FIG. 6 is a schematic plan view illustrating an example of a pixel according to a first exemplary embodiment.

FIG. 7 is a cross sectional diagram of an example of a pixel according to the first exemplary embodiment.

FIG. 8 is a cross sectional diagram of an example of a pixel according to a second exemplary embodiment.

FIG. 9 is a cross sectional diagram of an example of a pixel according to a third exemplary embodiment.

FIG. 10 is a cross sectional diagram of an example of a pixel according to a fourth exemplary embodiment.

FIG. 11 is a cross sectional diagram of an example of a pixel according to a fifth exemplary embodiment.

FIG. 12 is a cross sectional diagram of an example of a pixel according to a sixth exemplary embodiment.

FIG. 13 is a cross sectional diagram of an example of a pixel according to a seventh exemplary embodiment.

FIG. 14 is a cross sectional diagram of an example of a pixel according to an eighth exemplary embodiment.

FIG. 15 is a cross sectional diagram of an example of a pixel according to a ninth exemplary embodiment.

FIGS. 16A to 16C are block diagrams illustrating an example of an apparatus according to a tenth exemplary embodiment.

### DESCRIPTION OF THE EMBODIMENTS

The following exemplary embodiments are intended to embody the technical idea of the present disclosure and do not limit the present disclosure. Sizes and positional relationships of members illustrated in the drawings are sometimes exaggerated to clarity the description. In the following description, the same components are denoted by the same reference numerals, and descriptions thereof may be omitted.

Exemplary embodiments of the present disclosure will be described in detail below with reference to the drawings. In the following description, the terms which designate specific directions or positions (e.g., “up”, “down”, “right”, “left”, and other terms including such terms) are used as needed. Such terms are used for clear understanding of the exemplary embodiments with reference to the drawings, and the technical scope of the present disclosure is not limited by the meanings of the terms.

The term “plan view” as used herein refers to a view in a direction perpendicular to a light incidence surface of a semiconductor layer. The term “sectional view” as used herein refers to a view of a section in a direction perpendicular to the light incidence surface of the semiconductor layer.

If the light incidence surface of the semiconductor layer is a rough surface when the surface is viewed microscopically, a planar view is defined based on the light incidence surface of the semiconductor layer when viewed macroscopically.

The semiconductor layer includes a first surface, and a second surface on which light is incident. The second surface is opposite to the first surface.

The term “depth direction” as used herein refers to a direction from the first surface to the second surface of the semiconductor layer on which avalanche photodiodes (APDs) are arranged. Hereinafter, the “first surface” may also be referred to as a “front surface”, and the “second surface” may also be referred to as a “back surface”. The term “depth” of a certain point or a certain region within the semiconductor layer refers to as a distance of the point or the region from the first surface (front surface). Assuming that there are a point (or region) Z1 of which the distance (depth) from the first surface is d1 and a point (or region) Z2 of which the distance (depth) from the first surface is d2, when d1>d2 holds, this may be expressed as “Z1 is deeper than Z2”, or “Z2 is shallower than Z1”. Assuming that there is also a point (or region) Z3 of which the distance (depth) from the first surface is d3, when d1>d3>d2 holds, this may be expressed as “Z3 is at a depth between Z1 and Z2”, “Z3 is between Z1 and Z2 with respect to the depth direction”, or the like.

In the following description, assume that an anode of an APD is fixed to a potential and a signal is taken out of a cathode of the APD. Accordingly, a semiconductor region of a first conductivity type where electric charges having the same polarity as that of signal charges are the majority carriers is an n-type semiconductor region, and a semiconductor region of a second conductivity type where electric charges having a polarity different from that of signal charges are the majority carriers is a p-type semiconductor region. The present disclosure is also applicable to a configuration in which the cathode of the APD is fixed to a potential and a signal is taken out of the anode of the APD. In this case, the semiconductor region of the first conductivity type where electric charges having the same polarity as that of signal charges are the majority carriers is the p-type semiconductor region, and the semiconductor region of the second conductivity type where electric charges having a polarity different from that of signal charges are the majority carriers is the n-type semiconductor region. A configuration example where one of the nodes of the APD is fixed to a potential will be described below. However, both nodes of the APD may be variable in potential.

The term “impurity concentration” as used herein refers to a net impurity concentration compensated for impurities of opposite conductivity type. In other words, the term “impurity concentration” refers to a net doping concentration. A region in which a p-type additive impurity concentration is higher than an n-type additive impurity concentration is the p-type semiconductor region. In contrast, a region in which the n-type additive impurity concentration is higher than the p-type additive impurity concentration is the n-type semiconductor region.

In the following exemplary embodiments, a connection between circuit elements may be described. In this case, even when another element is interposed between elements of interest, it is assumed that the elements of interest are connected, unless otherwise noted. For example, assume that an element “A” is connected to one of nodes of a capacitive element “C” including a plurality of nodes and an element “B” is connected to another node of the capacitive element “C”. Even in this case, it is assumed that the element “A” and the element “B” are connected, unless otherwise noted.

Each metallic member such as a wire and a pad described herein may be made of a single elemental metal, or may be formed of a mixture (alloy). For example, a wire described as a copper wire may be made of elemental copper or may principally contain copper and additionally contain another component. For example, a pad to be connected to an external terminal may be made of elemental aluminum or may principally contain aluminum and additionally contain another component. The copper wire and the aluminum pad described herein are merely examples, and can be replaced with various types of metal.

The wire and the pad described herein are merely examples of metallic members used in photoelectric conversion devices, and other metallic members are also applicable.

In the following exemplary embodiments, an image capturing device will be mainly described as an example of a photoelectric conversion device. However, the exemplary embodiments are not limited only to an image capturing device, and are also applicable to other examples of the photoelectric conversion device. Other examples of the photoelectric conversion device include a distance measurement device (device for measuring a distance, for example, using focus detection or Time of Flight (ToF)) and a photometric device (device for measuring, for example, the amount of incident light).

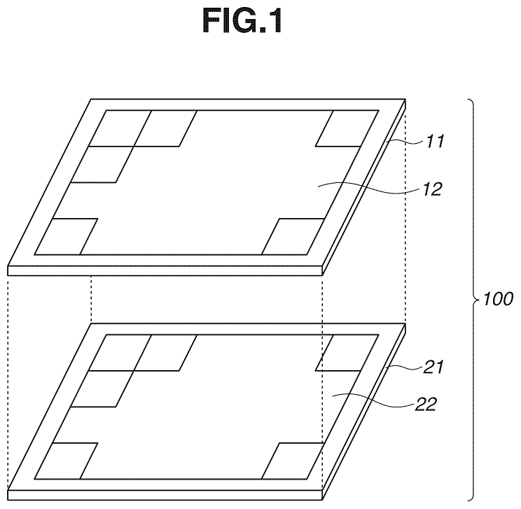

Configurations that are common to the exemplary embodiments of the photoelectric conversion device according to the present disclosure and a method for driving the photoelectric conversion device will be described with reference to FIGS. 1 to 5B.

FIG. 1 illustrates a configuration example of a photoelectric conversion device 100 according to an exemplary embodiment of the present disclosure. A configuration example in which the photoelectric conversion device 100 is a stacked photoelectric conversion device will be described. Specifically, the photoelectric conversion device 100 having a configuration in which two substrates, e.g., a sensor substrate 11 and a circuit substrate 21, are stacked and are electrically connected to each other will be described as an example. However, the photoelectric conversion device according to the present exemplary embodiment is not limited to this example. For example, the photoelectric conversion device may have a configuration in which components included in the sensor substrate 11 and components included in the circuit substrate 21 are provided in a common semiconductor layer as described below. The photoelectric conversion device having a configuration in which components included in the sensor substrate 11 and components included in the circuit substrate 21 are provided in the common semiconductor layer is also hereinafter referred to as a non-stacked photoelectric conversion device.

The sensor substrate 11 includes a first semiconductor layer including a photoelectric conversion unit 102 to be described below and a first wiring structure. The circuit substrate 21 includes a second semiconductor layer including circuits such as a signal processing unit 103 to be described below and a second wiring structure. The photoelectric conversion device 100 has a configuration in which the second semiconductor layer, the second wiring structure, the first wiring structure, and the first semiconductor layer are stacked in this order.

FIG. 1 illustrates a configuration example of a back-illuminated type photoelectric conversion device in which light enters from the first surface of the first semiconductor layer of the sensor substrate 11 and the circuit substrate 21 is provided on the second surface that is opposite to the first surface of the first semiconductor layer. In the non-stacked photoelectric conversion device, the surface on which a transistor for the signal processing unit 103 is provided is referred to as the second surface.

In the back-illuminated type photoelectric conversion device serving as the stacked photoelectric conversion device, the first surface that is opposite to the second surface of the semiconductor layer is the light incidence surface. In a front-illuminated type photoelectric conversion device, the second surface of the semiconductor layer is the light incidence surface.

The following description is made assuming that the sensor substrate 11 and the circuit substrate 21 are diced chips. However, the sensor substrate 11 and the circuit substrate 21 are not limited to chips. For example, the sensor substrate 11 and the circuit substrate 21 may be wafers. The sensor substrate 11 and the circuit substrate 21 may also be stacked in a wafer state and then diced, or may be obtained by stacking diced chips and joining the chips together.

The sensor substrate 11 is provided with a pixel region 12 and the circuit substrate 21 is provided with a circuit region 22 that processes signals detected in the pixel region 12.

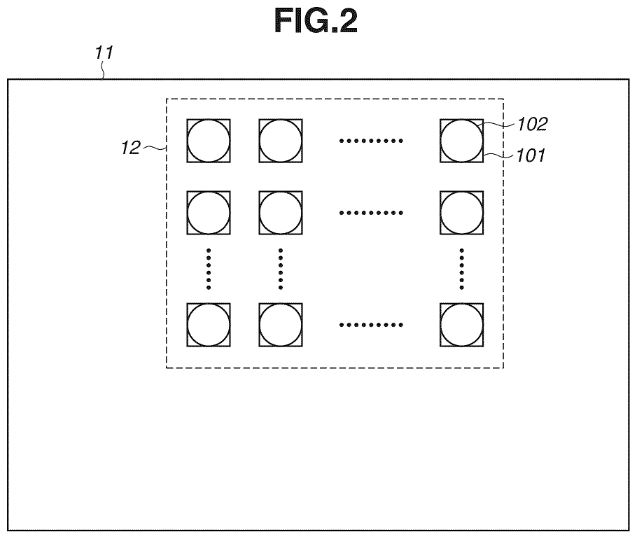

FIG. 2 illustrates a layout example of the sensor substrate 11. Pixels 101 each including the photoelectric conversion unit 102 including an APD are two-dimensionally arrayed to form the pixel region 12.

Typically, each pixel 101 is a pixel for forming an image. If each pixel 101 is used for ToF, the pixel 101 does not necessarily form an image. In other words, each pixel 101 may be a pixel for measuring time when light has reached and an amount of light.

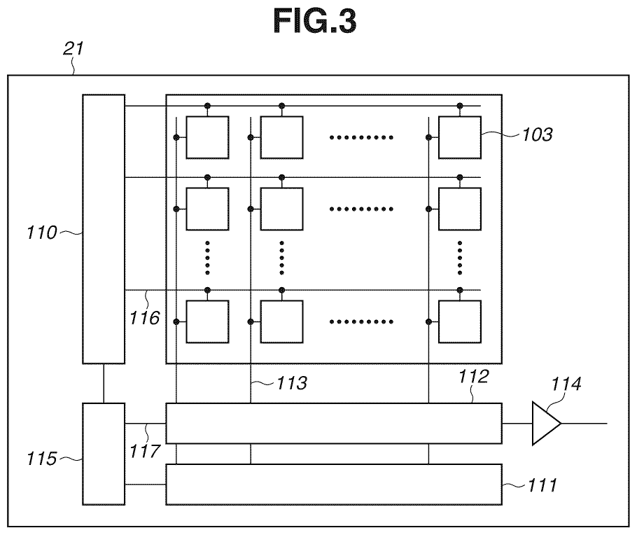

FIG. 3 is a circuit diagram illustrating the circuit substrate 21. The circuit substrate 21 includes the signal processing unit 103 for processing electric charges photoelectrically converted by the photoelectric conversion unit 102 illustrated in FIG. 2, a read-out circuit 112, a control pulse generation unit 115, a horizontal scanning circuit unit 111, signal lines 113, and a vertical scanning circuit unit 110.

The photoelectric conversion unit 102 illustrated in FIG. 2 and the signal processing unit 103 illustrated in FIG. 3 are electrically connected via a connection wire provided for each pixel 101.

The vertical scanning circuit unit 110 receives a control pulse supplied from the control pulse generation unit 115, and supplies the control pulse to each pixel 101. A logic circuit, such as a shift register or an address decoder, is used as the vertical scanning circuit unit 110.

The control pulse generation unit 115 includes a signal generation unit 215 that generates a control signal for a switch 202 to be described below. The signal generation unit 215 generates a pulse signal for controlling the switch 202 as described below. For example, the signal generation unit 215 may generate the control signal common to the plurality of pixels 101 in the pixel region 12, or the signal generation unit 215 may generate the control signals for each of the pixels 101. In the case of generating the common pulse signal, the common pulse signal is generated such that at least one of the cycles, the number of pulses, and the pulse width of a pulse signal for controlling an exposure period corresponds to the exposure period. In the case of controlling the control signals for the pixels 101, respectively, the control signals can be generated using an input signal output from the control pulse generation unit 115 and a signal for controlling the exposure period. The control pulse generation unit 115 may include, for example, a frequency-divider circuit. This configuration can make control processing simple and reduce an increase in the number of elements.

The signal output from the photoelectric conversion unit 102 in each pixel 101 is processed by the signal processing unit 103. The signal processing unit 103 is provided with a counter, a memory, and the like, and digital values are held in the memory.

The horizontal scanning circuit unit 111 outputs a control pulse to the signal processing unit 103 in each pixel 101 to sequentially select columns to read out signals from the memory of each pixel 101 in which digital signals are held.

In a selected column, signals from the signal processing unit 103 in each pixel 101 selected by the vertical scanning circuit unit 110 are output to the corresponding signal line 113.

The signals output to the signal line 113 are output to an external recording unit or signal processing unit of the photoelectric conversion device 100 via an output circuit 114.

In the example illustrated in FIG. 2, the pixels 101 in the pixel region 12 may be one-dimensionally arranged. Each pixel 101 may not be provided with the function of the signal processing unit 103. For example, one signal processing unit 103 may be shared by a plurality of pixels 101 and signal processing may be sequentially performed.

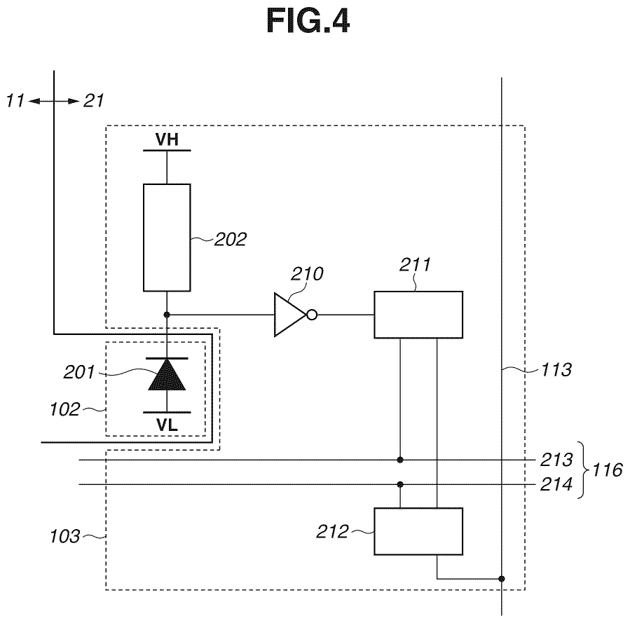

FIG. 4 is an example of a block diagram including equivalent circuits illustrated in FIGS. 2 and 3. In the example illustrated in FIG. 2, the photoelectric conversion unit 102 including the APD 201 is provided on the sensor substrate 11, and the other members are provided on the circuit substrate 21.

The APD 201 generates an electric charge pair corresponding to incident light by photoelectric conversion. The anode of the APD 201 is supplied with a voltage VL (first voltage). The cathode of the APD 201 is supplied with a voltage VH (second voltage) that is higher than the voltage VL supplied to the anode of the APD 201. The anode and the cathode are supplied with reverse bias voltage at which the APD 201 performs an avalanche multiplication operation. In the state where such voltage is supplied, electric charges generated by incident light cause the avalanche multiplication, which generates an avalanche current.

In a case where reverse bias voltage is supplied, an APD is operated in a Geiger mode or a linear mode. In the Geiger mode, the APD is operated with a potential difference between the anode and the cathode that is larger than a breakdown voltage. In the linear mode, the APD is operated with a potential difference between the anode and the cathode that is near a breakdown voltage, or with a voltage difference less than or equal to the breakdown voltage. The APD operated in the Geiger mode is referred to as a single photon avalanche diode (SPAD). For example, the voltage VL (first voltage) is −30 V (volts) and the voltage VH (second voltage) is 1 V. The APD 201 may be operated in the linear mode or in the Geiger mode. The potential difference of the SPAD is larger than that of the APD in the linear mode, and the voltage proof effect is more prominent.

A switch 202 is connected to the APD 201 and a control line supplied with the drive voltage VH. The switch 202 is connected to one of the anode and the cathode of the APD 201.

The switch 202 switches the potential difference between the anode and the cathode of the APD 201 to one of a first potential difference that causes the avalanche multiplication and a second potential difference that does not cause the avalanche multiplication. Switching from the second potential difference to the first potential difference is hereinafter also referred to as “ON” of the switch 202, and switching from the first potential difference to the second potential difference is hereinafter also referred to as “OFF” of the switch 202. The switch 202 functions as a quench element. The switch 202 functions as a load circuit (quench circuit) during signal multiplication by avalanche multiplication, and has a function (quench operation) to suppress the voltage to be supplied to the APD 201 to thereby suppress avalanche multiplication. The switch 202 also has a function (recharge operation) to cause a current corresponding to a voltage drop to flow in the quench operation, thereby restoring the voltage to be supplied to the APD 201 to the drive voltage VH. In other words, the switch 202 functions as a control circuit for controlling the occurrence of avalanche multiplication in the APD 201.

The switch 202 can be composed of, for example, a metal oxide semiconductor (MOS) transistor. The control signal for the switch 202 that is supplied from the signal generation unit 215 is applied to a gate electrode of the MOS transistor forming the switch 202. In the present exemplary embodiment, ON and OFF of the switch 202 are controlled by controlling the voltage to be applied to the gate electrode of the switch 202.

The signal processing unit 103 includes a waveform shaping unit 210, a counter circuit 211, and a selection circuit 212. In the present exemplary embodiment, the signal processing unit 103 may include at least one of the waveform shaping unit 210, the counter circuit 211, and the selection circuit 212.

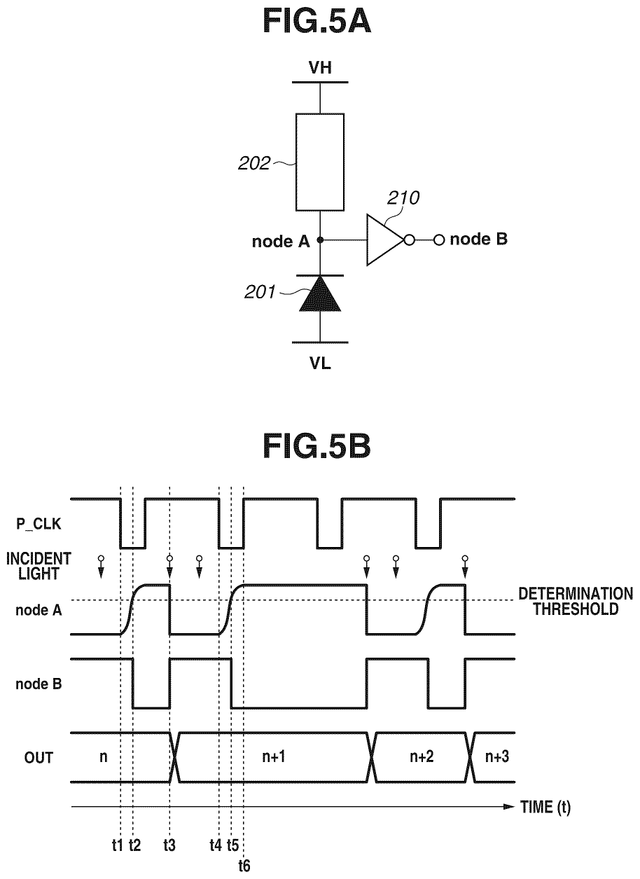

The waveform shaping unit 210 shapes a potential change at the cathode of the APD 201 that is obtained upon detection of a photon, and outputs a pulse signal. An input-side node of the waveform shaping unit 210 is referred to as a node A, and an output-side node of the waveform shaping unit 210 is referred to as a node B. The waveform shaping unit 210 changes the output potential at the node B depending on whether the potential input to the node A is more than or equal to a predetermined value or lower than the predetermined value. For example, as illustrated in FIGS. 5A and 5B, when the input potential to the node A is a high potential that is more than or equal to a determination threshold, the output potential from the node B is at a low level. When the input potential to the node A is a low potential that is lower than the determination threshold, the output potential from the node B is at a high level. For example, an inverter circuit is used as the waveform shaping unit 210. While FIG. 4 illustrates an example where one inverter is used as the waveform shaping unit 210, a circuit including a plurality of inverters connected in series, or another circuit having a waveform shaping effect may be used.

The quench operation and the recharge operation can be performed using the switch 202 in accordance with avalanche multiplication in the APD 201. However, in some cases, electric charges generated in the APD 201 cannot be determined to be an output signal depending on the detection timing of the photon. For example, assume a case where the recharge operation is performed in a state where avalanche multiplication occurs in the APD 201 and the potential at the node A is at the low level. In general, the determination threshold for the waveform shaping unit 210 is set to a potential higher than the potential difference at which avalanche multiplication occurs in the APD 201. When a photon is incident on the APD 201 at a potential at which avalanche multiplication can occur in the APD 201 in a state where the potential at the node A is lower than the determination threshold in the recharge operation, avalanche multiplication occurs in the APD 201 and the voltage at the node A decreases. In other words, since the potential at the node A decreases at a voltage lower than the determination threshold, a potential change crossing the determination threshold does not occur, so that the output potential at the node B does not change. Accordingly, the detected photon is not determined to be a signal even when avalanche multiplication occurs. Especially under high illuminance, photons consecutively enter the APD in a short period, and thus the photons are less likely to be determined to be signals. For this reason, in spite of a high illuminance, a discrepancy is more likely to occur between the number of actual incident photons and the number of output signals.

In contrast to this, by switching between the ON state and the OFF state of the switch 202 by applying the control signal P_CLK to the switch 202, photons can be determined to be signals also in a case where photons consecutively enter the APD 201 in a short time. An example where the control signal P_CLK is a pulse signal output at a repeat cycle will be described with reference to FIGS. 5A and 5B. In other words, a configuration in which the ON state and the OFF state of the switch 202 are switched at a predetermined clock frequency will be described with reference to FIGS. 5A and 5B. However, the effect of suppressing an increase in power consumption of the photoelectric conversion device can be obtained even if a pulse signal is not a signal output at a repeat cycle.

The counter circuit 211 counts the number of pulse signals output from the waveform shaping unit 210, and holds a count value. When a control pulse pRES is supplied via a drive line 213, the number of signals held in the counter circuit 211 is reset.

A control pulse pSEL is supplied to the selection circuit 212 from the vertical scanning circuit unit 110 illustrated in FIG. 3 via a drive line 214 illustrated in FIG. 4 (not illustrated in FIG. 3), thereby switching electric connection and separation between the counter circuit 211 and the signal line 113. The selection circuit 212 includes, for example, a buffer circuit for outputting a signal.

A switch, such as a transistor, may be provided between the switch 202 and the APD 201 or between the photoelectric conversion unit 102 and the signal processing unit 103, to thereby switch the electric connection. Similarly, the voltage VH or the voltage VL to be supplied to the photoelectric conversion unit 102 may be electrically switched using a switch, such as a transistor.

The present exemplary embodiment described above illustrates a configuration example using the counter circuit 211. However, the photoelectric conversion device 100 may be configured to obtain a pulse detection timing using a time-to-digital converter (TDC) or a memory in place of the counter circuit 211. In this case, the generation timing of the pulse signal output from the waveform shaping unit 210 is converted into a digital signal by the TDC. To measure the timing of the pulse signal, the TDC is supplied with a control pulse pREF (reference signal) from the vertical scanning circuit unit 110 illustrated in FIG. 3 via a drive line. The TDC obtains, as a digital signal, a value based on an input timing of a signal output from each pixel 101 as a relative time with the control pulse pREF as a reference.

FIGS. 5A and 5B schematically illustrate a relationship among the control signal P_CLK for the switch 202, the potential at the node A, the potential at the node B, and the output signal. In the present exemplary embodiment, when the control signal P_CLK is at the high level, the drive voltage VH is less likely to be supplied to the APD 201, and when the control signal P_CLK is at the low level, the drive voltage VH is supplied to the APD 201. The control signal P_CLK at the high level has, for example, 1 V, and the control signal P_CLK at the low level has, for example, 0 V. When the control signal P_CLK is at the high level, the switch 202 is turned off, and when the control signal P_CLK is at the low level, the switch 202 is turned on. A resistance value of the switch 202 when the control signal P_CLK is at the high level is higher than the resistance value of the switch 202 when the control signal P_CLK is at the low level. When the control signal P_CLK is at the high level, the recharge operation can be hardly performed even if avalanche multiplication occurs in the APD 201, so that the potential to be supplied to the APD 201 is less than or equal to the breakdown voltage of the APD 201. Accordingly, the avalanche multiplication operation in the APD 201 stops.

The switch 202 may be composed of one transistor and the quench operation and the recharge operation may be performed using one transistor. This configuration makes it possible to reduce the number of circuits as compared with a case where the quench operation and the recharge operation are performed by different circuit elements from each other. In particular, if each pixel 101 includes a counter circuit and reads out a signal from the SPAD, it may be desirable to reduce a circuit area used for the switch 202 to provide the counter circuit, and an effect obtained by forming the switch 202 using one transistor becomes prominent.

As illustrated in FIG. 5A, at time t1, the control signal P_CLK changes from the high level to the low level, the switch 202 is turned on, and the recharge operation of the APD 201 starts. As a result, the potential at the cathode of the APD 201 transitions to the high level. The potential difference between the potential applied to the anode of the APD 201 and the potential applied to the cathode of the APD 201 becomes a state where avalanche multiplication can occur. The potential at the cathode is equal to the potential at the node A. Accordingly, when the potential at the cathode transitions from the low level to the high level, at time t2, the potential at the node A is more than or equal to the determination threshold. In this case, the pulse signal output from the node B is reversed and transitions from the high level to the low level. Thereafter, the potential difference between the drive voltage VH and the drive voltage VL is applied to the APD 201. The control signal P_CLK transitions to the high level and the switch 202 is turned off.

Next, at time t3, when a photon is incident on the APD 201, avalanche multiplication occurs in the APD 201, so that the voltage at the cathode decreases. In other words, the voltage at the node A decreases. When the amount of voltage drop further increases and the difference in voltage to be applied to the APD 201 decreases, avalanche multiplication in the APD 201 stops as in time t2, and the voltage level at the node A stops dropping from a certain fixed value. If the voltage at the node A becomes lower than the determination threshold value while the voltage at the node A is dropping, the voltage at the node B transitions from the low level to the high level. In other words, a portion with an output waveform exceeding the determination threshold at the node A is subjected to waveform shaping by the waveform shaping unit 210, and is output as a signal at the node B. The signal is then counted by the counter circuit 211, and the count value of the counter signal output from the counter circuit 211 is incremented by 1 least significant bit (LSB).

While a photon is incident on the APD 201 during a period between time t3 and time t4, the switch 202 is in the OFF state and the voltage applied to the APD 201 does not have a potential difference at which avalanche multiplication can occur. Thus, the voltage level at the node A does not exceed the determination threshold.

At time t4, the control signal P_CLK changes from the high level to the low level and the switch 202 is turned on. Along with this operation, a current compensating for a voltage drop flows to the node A from the drive voltage VH, and the voltage at the node A transitions to the original voltage level. In this case, at time t5, the voltage at the node A is more than or equal to the determination threshold, so that the pulse signal at the node B is reversed and transitions from the high level to the low level.

At time t6, the voltage level at the node A is settled at the original voltage level and the control signal P_CLK transitions from the low level to the high level. Accordingly, the switch 202 is turned off. Even after that, the potentials at each node, each signal line, and the like change depending on the control signal P_CLK or the incidence of a photon as described above from time t1 to time t6.

Photoelectric conversion devices according to exemplary embodiments will be described below.

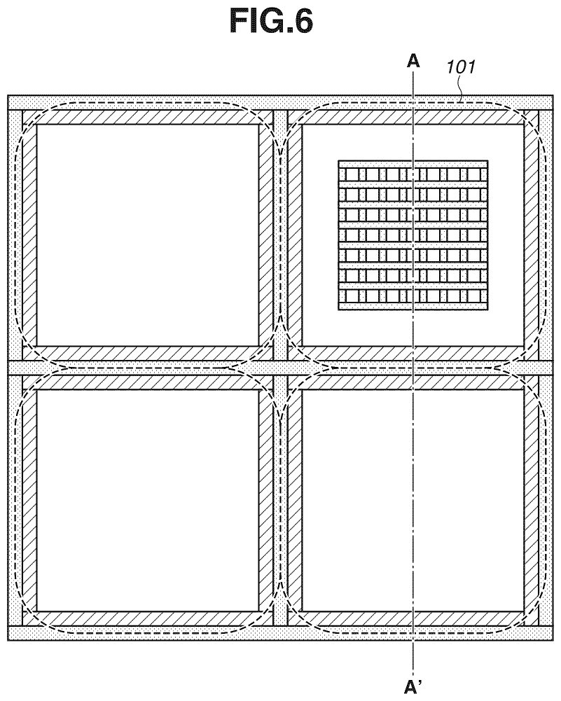

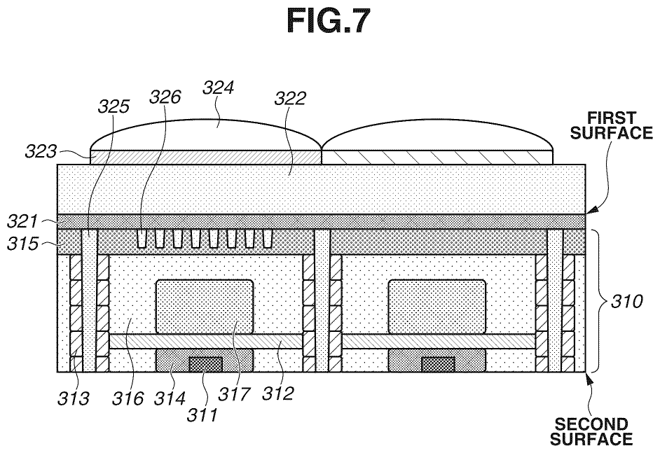

FIG. 6 is a schematic plan view illustrating an example of pixels according to a first exemplary embodiment. FIG. 7 is a sectional view illustrating a part of a section taken along a line A-A′ in FIG. 6. FIG. 7 is a sectional view of two pixels 101.

A semiconductor layer 310 is formed of, for example, silicon. On the first surface (light incidence surface) of the semiconductor layer 310, a pinning film 321, a planarization layer 322, and a filter layer 323 are provided in this order, and a microlens 324 corresponding to each pixel 101 is further provided above the layers. In other words, the photoelectric conversion device according to the first exemplary embodiment has a so-called back-illuminated structure in which light enters the semiconductor layer 310 from the first surface side.

The pinning film 321 is formed of a dielectric material including a negative fixed charge, and is provided on the entire first surface of the semiconductor layer 310. Examples of materials that can be selected for the pinning film 321 include hafnium oxide, aluminum oxide, zirconium oxide, titanium oxide, tantalum oxide, and ruthenium oxide. Among these examples, aluminum oxide and hafnium oxide may be desirable. The pinning film 321 may be formed of a plurality of layers.

On the light incidence side of the pinning film 321, there are provided the planarization layer 322, the filter layer 323, and the microlens 324. Various optical filters, such as a color filter, an infrared light cut filter, and a monochrome filter can be used for the filter layer 323. A red, green, and blue (RGB) filter, a red, green, blue, and white (RGBW) color filter, or the like can be used as the color filter.

Each pixel 101 has sensitivity to a specific wavelength, such as RGB visible light or near-infrared (NIR), depending on the spectral transmittance of the filter layer 323 provided on the light incidence side. An example where a long wavelength in each pixel 101 according to the present exemplary embodiment corresponds to a near-infrared light wavelength (780 to 3000 nm) and a short wavelength corresponds to a visible light wavelength (380 to 780 nm) will be described below.

For example, a pixel having a peak wavelength of visible light is used as an image capturing pixel. For example, a pixel having a peak wavelength of near-infrared light is used as a distance measurement pixel using ToF. In the present disclosure, how to distinguish (bandwidth of each of) the long wavelength and the short wavelength is not limited to the above-described example. For example, a region with a longer wavelength in the visible light region may be used as the long wavelength, or a region with a longer wavelength than near-infrared light may be used as the long wavelength while near-infrared light is used as the short wavelength.

The semiconductor layer 310 includes a first semiconductor region 311, a fourth semiconductor region 314, a sixth semiconductor region 316, and a seventh semiconductor region 317, which are n-type semiconductor regions. Further, the semiconductor layer 310 includes a second semiconductor region 312, a third semiconductor region 313, and a fifth semiconductor region 315, which are p-type semiconductor regions.

According to the present exemplary embodiment, in the sectional view illustrated in FIG. 7, the n-type first semiconductor region 311 is formed near the second surface opposed to the first surface (light incidence surface), and the n-type fourth semiconductor region 314 is formed in the vicinity of the n-type first semiconductor region 311. The p-type second semiconductor region 312 is formed at a position where the second semiconductor region 312 overlaps the first semiconductor region 311 and the fourth semiconductor region 314 in a planar view. The n-type seventh semiconductor region 317 is further provided at a position where the seventh semiconductor region 317 overlaps the second semiconductor region 312 in a planar view, and the n-type sixth semiconductor region 316 is formed in the vicinity of the seventh semiconductor region 317.

The first semiconductor region 311 has an n-type impurity concentration higher than that of the fourth semiconductor region 314 and the seventh semiconductor region 317. A pn junction is formed between the p-type second semiconductor region 312 and the n-type first semiconductor region 311. When the impurity concentration of the second semiconductor region 312 is set to be lower than the impurity concentration of the first semiconductor region 311, all regions in the semiconductor region 312 that overlap the center of the first semiconductor region 311 in a planar view become a depletion layer region.

In this case, the potential difference between the first semiconductor region 311 and the second semiconductor region 312 is larger than the potential difference between the second semiconductor region 312 and the seventh semiconductor region 317. Further, this depletion layer region extends up to a partial region of the first semiconductor region 311, and a strong electric field is induced in the extended depletion layer region. This strong electric field causes avalanche multiplication in the depletion layer region extended to the partial region of the first semiconductor region 311, and a current based on amplified electric charges is output as signal charges. When light that has entered the pixel 101 is photoelectrically converted and avalanche multiplication occurs in this depletion layer region (avalanche multiplication region), the generated electric charges are collected in the first semiconductor region 311.

In the example illustrated in FIG. 7, the fourth semiconductor region 314 and the seventh semiconductor region 317 are formed with substantially the same size. However, the size of each of the fourth semiconductor region 314 and the seventh semiconductor region 317 is not limited to this example. For example, the seventh semiconductor region 317 may be formed with a size larger than a size of the fourth semiconductor region 314, and electric charges may be collected in the first semiconductor region 311 from a wide range.

The fourth semiconductor region 314 is not limited to an n-type semiconductor region, but instead may be a p-type semiconductor region. In this case, the impurity concentration in the fourth semiconductor region 314 is set to be lower than the impurity concentration in the second semiconductor region 312. If the impurity concentration in the fourth semiconductor region 314 is extremely high, an avalanche multiplication region is formed between the fourth semiconductor region 314 and the first semiconductor region 311, which may lead to an increase in dark count rate (DCR).

The pixels 101 are isolated by a pixel isolation portion 325 having a trench structure, and the third semiconductor region 313 formed around the pixel isolation portion 325 isolates the adjacent pixels 10 with a potential barrier. Since the pixels 101 are isolated by the potential of the fourth semiconductor region 314, the trench structure, such as the pixel isolation portion 325, serving as a pixel isolation portion is not essential. Even when the pixel isolation portion 325 having a trench structure is provided, the depth and the position of the pixel isolation portion 325 are not limited to those in the configuration illustrated in FIG. 7.

The pixel isolation portion 325 may be a deep trench isolation (DTI) penetrating through the semiconductor layer 310, or may be a DTI not penetrating through the semiconductor layer 310. A metal may be embedded in the DTI to improve a light blocking performance. The pixel isolation portion 325 may be formed of a silicon monoxide (SiO), a fixed charge film, a metallic member, polysilicon (Poly-Si), or a combination thereof. The pixel isolation portion 325 may be formed to surround the entire perimeter of the pixel 101 in a planar view, or may be formed only in a portion facing a side of the pixel 101. A voltage may be applied to an embedded member to induce electric charges on a trench interface to reduce the DCR.

A diffractive region 326 includes a plurality of recessed portions (first recessed portion) formed on the first surface (light incidence surface) side of the fifth semiconductor region 315. The first recessed portion has a trench structure such as shallow trench isolation (STI). An insulating material made of SiO or silicon nitride (SiN) may be embedded in each recessed portion, or a metal such as tungsten (W) or aluminum (Al) may be embedded in each recessed portion. The diffractive region 326 is surrounded by the p-type fifth semiconductor region 315 and diffracts light incident on the pixel 101. The incident light travels obliquely within the semiconductor layer 310. This makes it possible to secure an optical path length more than or equal to the thickness of the semiconductor layer 310 and to photoelectrically convert more light than that when the diffractive region 326 is not provided.

The seventh semiconductor region 317 and the diffractive region 326 are formed in an overlapping manner in a planar view. The area where the seventh semiconductor region 317 and the diffractive region 326 overlap in a planar view is larger than the area of a portion of the seventh semiconductor region 317 that does not overlap the diffractive region 326.

A movement time for electric charges generated at positions far from the avalanche multiplication region formed between the first semiconductor region 311 and the seventh semiconductor region 317 to reach the avalanche multiplication region is longer than that for electric charges generated at positions close to the avalanche multiplication region. This may lead to an increase in timing jitter. The provision of the seventh semiconductor region 317 and the diffractive region 326 in an overlapping manner in a planar view makes it possible to enhance the electric field in a photodiode deep portion and to reduce a time for collecting electric charges generated at positions far from the avalanche multiplication region. This leads to a reduction in timing jitter.

The fifth semiconductor region 315 three-dimensionally covers the diffractive region 326, thereby reducing the generation of thermally-excited charges at interface portions of the diffractive region 326. This reduces the DCR of the pixel 101.

In this case, only a long-wavelength pixel (first pixel) having a peak wavelength in the long wavelength of incident light on the semiconductor layer 310 is provided with the diffractive region 326, and a short-wavelength pixel (second pixel) having a peak wavelength in the short wavelength of incident light on the semiconductor layer 310 is not provided with the diffractive region 326. For example, RGB pixels are not provided with the diffractive region 326. This is because, for example, short-wavelength light has a short penetration length to the semiconductor layer 310 and thus has a limited effect of improving the sensitivity by extending the optical path length, while there is a concern that a dark current can increase as silicon interfaces are increased by providing the diffractive region 326.

While the present exemplary embodiment described above illustrates an example of the structure including a plurality of recessed portions with a trench structure, such as STI, on the front surface of the semiconductor layer 301 as the diffractive region, the structure is not limited to this example. Any other structure capable of diffracting incident light may be used.

Like in the present exemplary embodiment, the long-wavelength pixel (first pixel) for, for example, photoelectrically converting near-infrared light is provided with the diffractive region to improve the sensitivity, and the short-wavelength pixel (second pixel) for, for example, photoelectrically converting visible light is not provided with the diffractive region. This configuration avoids the effect of deterioration in performance due to the diffractive region.

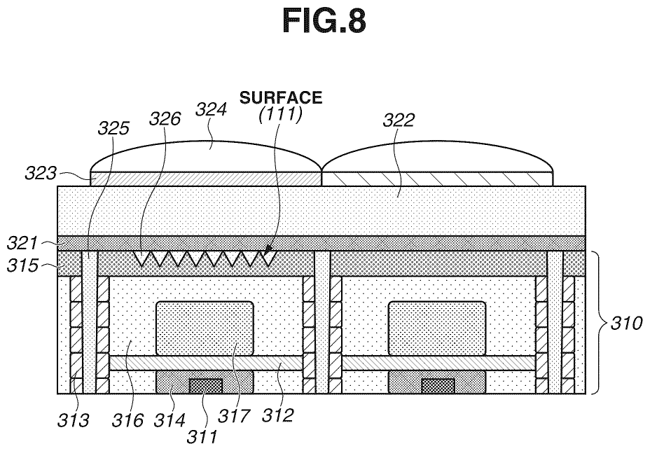

FIG. 8 is a schematic view illustrating an example of pixels 101 according to a second exemplary embodiment. The pixels 101 according to the second exemplary embodiment differ from the pixels 101 according to the first exemplary embodiment illustrated in FIG. 7 in regard to the shape of a plurality of recessed portions (first recessed portion) in the diffractive region 326. Descriptions of components similar to those illustrated in FIG. 7 will be omitted.

In the pixels 101 illustrated in FIG. 7, a plurality of columnar recessed portions, such as trench structures, are used for the diffractive region 326 in the long-wavelength pixel (first pixel). The second exemplary embodiment illustrated in FIG. 8 uses a structure including a plurality of recessed portions with a quadrangular pyramid shape in the diffractive region 326. The diffractive region 326 including the recessed portions with a quadrangular pyramid shape is formed by, for example, anisotropic wet etching. When the diffractive region 326 is formed by anisotropic wet etching, the front surface of the diffractive region 326 is a (111) surface.

With such a structure, the effect of improving the sensitivity in the long-wavelength pixel (first pixel) can be obtained like in the structure described in the first exemplary embodiment. Further, the configuration in which the short-wavelength pixel (second pixel) is not provided with the diffractive region makes it possible to reduce the deterioration in performance due to the diffractive region.

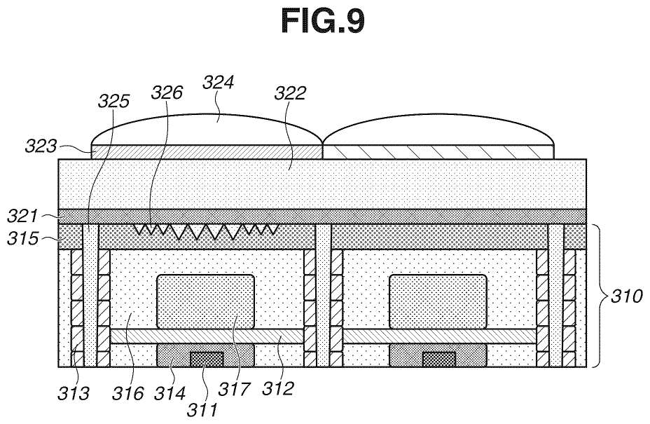

FIG. 9 is a schematic view illustrating an example of pixels 101 according to a third exemplary embodiment. The pixels 101 according to the third exemplary embodiment differ from the pixel 101 according to the second exemplary embodiment illustrated in FIG. 8 in regard to the shape of the diffractive region 326. Descriptions of components similar to those illustrated in FIG. 8 will be omitted.

In the pixels 101 illustrated in FIG. 8, a plurality of recessed portions with a quadrangular pyramid shape is used for the diffractive region 326. In each pixel 101 illustrated in FIG. 9, the interval between the adjacent recessed portions with a quadrangular pyramid shape in a central portion of the pixel 101 is different from that in a peripheral portion of the pixel 101.

If the interval between the adjacent recessed portions with a quadrangular pyramid shape in the central portion of the pixel 101 is set to an interval suitable for maximizing the optical path length, the effect of increasing the optical path length of the diffractive region 326 is reduced in the adjacent recessed portions with a quadrangular pyramid shape in the peripheral portion of the pixel 101. With this configuration, crosstalk that can occur between the plurality of pixels 101 can be suppressed.

In the example illustrated in FIG. 9, the interval between the recessed portions of the diffractive region 326 in the peripheral portion of the pixel 101 is smaller than the interval between the recessed portions of the diffractive region 326 in the central portion of the pixel 101. However, the magnitude relationship of the interval between the recessed portions may be reversed. While the present exemplary embodiment described above illustrates an example where the diffractive region 326 has a quadrangular pyramid shape, a trench structure, such as STI, may also be used.

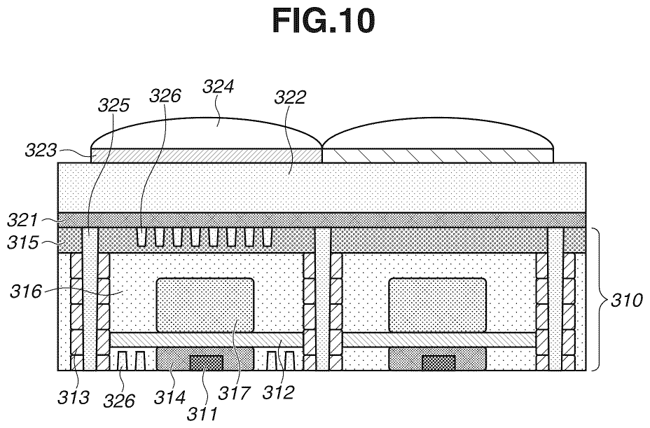

FIG. 10 is a schematic view illustrating an example of pixels 101 according to a fourth exemplary embodiment. The pixels 101 according to the fourth exemplary embodiment differ from the pixels 101 according to the first exemplary embodiment illustrated in FIG. 7 in regard to a location where the diffractive region 326 is provided. Descriptions of components similar to those illustrated in FIG. 7 will be omitted.

The pixels 101 illustrated in FIG. 10 have a configuration in which the diffractive region 326 is also provided on the surface (second surface) opposed to the light incidence surface (first surface) of the semiconductor layer 310. With this configuration, the optical path length can be further increased.

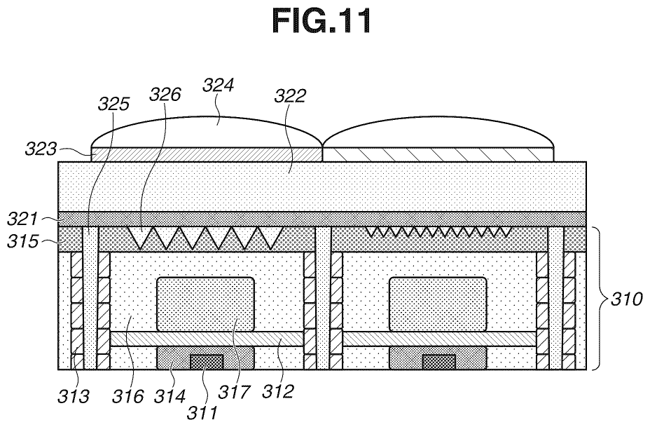

FIG. 11 is a schematic view illustrating an example of pixels 101 according to a fifth exemplary embodiment. The pixels 101 according to the fifth exemplary embodiment differ from the pixel 101 according to the second exemplary embodiment illustrated in FIG. 8 in that the interval between the adjacent recessed portions of the diffractive region 326 is changed for each pixel 101.

Descriptions of components similar to those illustrated in FIG. 8 will be omitted.

In the example illustrated in FIG. 11, the interval between the adjacent recessed portions of the diffractive region 326 is set to a large interval in the long-wavelength pixel (first pixel), and is set to a small interval in the short-wavelength pixel (second pixel). An optimum interval varies depending on the wavelength in the diffractive region 326. Thus, as illustrated in FIG. 11, a pattern in which the interval between the adjacent recessed portions of the diffractive region 326 is changed for each of pixels 101 with different peak wavelengths (or different colors) of incident light is formed to thereby obtain the sensitivity improvement effect.

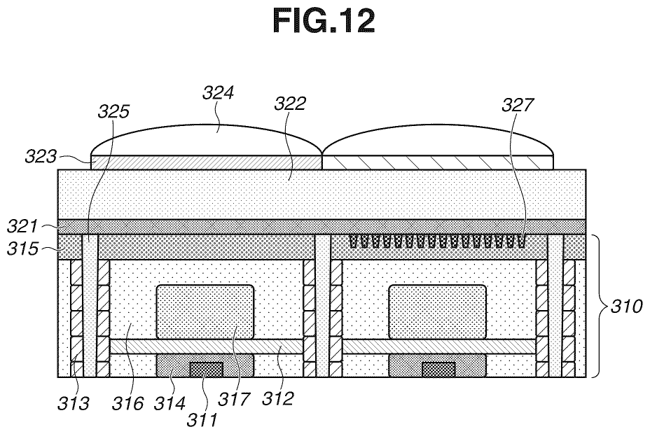

FIG. 12 is a schematic view illustrating an example of pixels 101 according to a sixth exemplary embodiment. The pixels 101 according to the sixth exemplary embodiment differ from the pixel 101 according to the first exemplary embodiment illustrated in FIG. 7 in that the long-wavelength pixel (first pixel) and the short-wavelength pixel (second pixel) are not provided with the diffractive region 326, and the short-wavelength pixel (second pixel) is provided with an anti-reflection (AR) region 327. Descriptions of components similar to those illustrated in FIG. 7 will be omitted.

FIG. 12 illustrates an example where the AR region 327 including a plurality of recessed portions (second recessed portion) arranged at a narrower interval than the interval between the adjacent recessed portions of the diffractive region 326 is provided on the light incidence surface side of the semiconductor layer 310. In the AR region 327, the dimensions of the recessed portions and the interval between the adjacent recessed portions are set to be smaller than the wavelength of incident light, and a change in refractive index on the front surface of the semiconductor layer 310 is made gradual, thereby obtaining the AR effect. In the example illustrated in FIG. 12, only the short-wavelength pixel (second pixel) is provided with the AR region 327, but the long-wavelength pixel (first pixel) may also be provided with the AR region 327. Since the AR effect of the AR region 327 depends on the wavelength, the structure of the AR region 327 may be determined depending on the peak wavelength of each pixel 101.

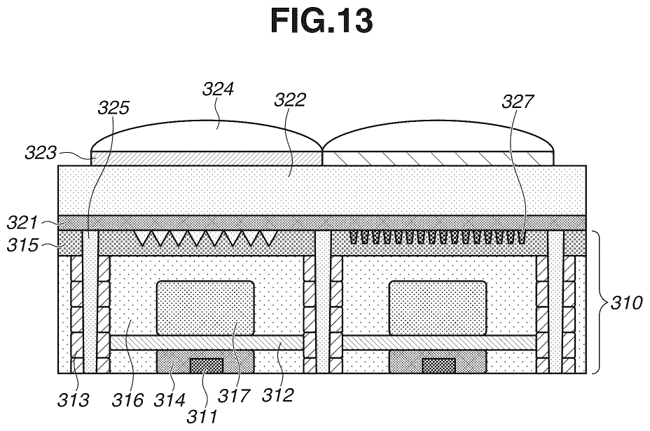

FIG. 13 is a schematic view illustrating an example of pixels 101 according to a seventh exemplary embodiment. Descriptions of components similar to those of the sixth exemplary embodiment illustrated in FIG. 12 will be omitted.

In the pixels 101 illustrated in FIG. 13, the long-wavelength pixel (first pixel) is provided with the diffractive region 326 for diffraction, and the short-wavelength pixel (second pixel) is provided with the AR region 327 for obtaining the AR effect.

With this configuration, the effect of improving the sensitivity in the long-wavelength pixel (first pixel) can be obtained and the AR effect in the short-wavelength pixel (second pixel) can be obtained.

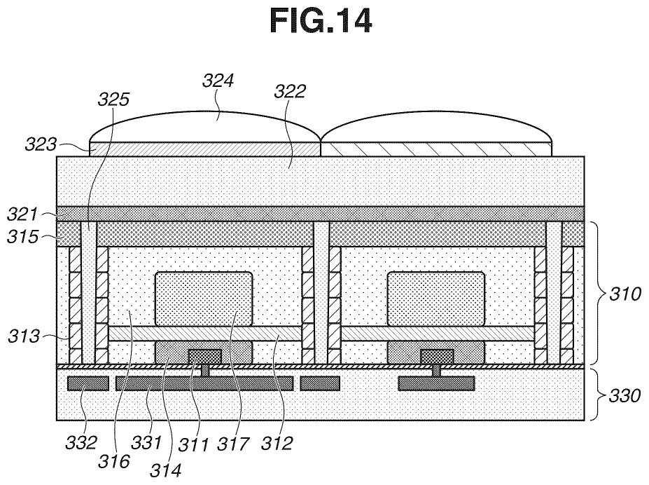

FIG. 14 is a schematic view illustrating an example of pixels 101 according to an eighth exemplary embodiment. Descriptions of components similar to those illustrated in FIG. 7 will be omitted.

In the example illustrated in FIG. 14, a wiring layer provided with wires, such as a cathode wire 331 and an anode wire 332, are provided on the second surface side of the semiconductor layer 310. The cathode wire 331 is a wire for supplying a voltage to one terminal (cathode terminal) of the APD, and the anode wire 332 is a wire for supplying a voltage to the other terminal (anode terminal) of the APD.

Light that has entered the semiconductor layer 310 is photoelectrically converted in the semiconductor layer 310. A part of the incident light reaches the wiring layer 330 without being photoelectrically converted, and is reflected by the cathode wire 331 and the anode wire 332, which are provided in the wiring layer, and is then returned to the semiconductor layer 310. The light passing through the wiring layer 330 by the reflection without being photoelectrically converted is also photoelectrically converted in the semiconductor layer 310.

In other words, the provision of a reflective metal (metal wire) using the cathode wire 331 and the anode wire 332 makes it possible to improve the sensitivity of the photoelectric conversion device. In particular, light with a longer wavelength that is less likely to be photoelectrically converted is more likely to enter a deeper region of the semiconductor layer 310. This increases the sensitivity improvement effect using the reflective metal structure.

In particular, in the SPAD, if the cathode wire 331 serving as the reflective metal is provided below the avalanche multiplication region, the cathode wire 331 may be affected by the potential from the reflective metal. Light with a short wavelength is less likely to enter a deep region of the semiconductor layer 310. Thus, the effect of reflection is small even when reflective metal is provided in the short-wavelength pixel (second pixel).

In view of the above, according to the present exemplary embodiment, only the long-wavelength pixel (first pixel) is provided with a reflective metal with a large area, and the short-wavelength pixel (second pixel) is provided with a reflective metal with a smaller area than that of the long-wavelength pixel (first pixel).

As a modified example of the present exemplary embodiment, a configuration may be employed in which only the long-wavelength pixel (first pixel) is provided with a reflective metal with a large area and the short-wavelength pixel (second pixel) is not provided with any reflective metal.

With this configuration, reflection on the reflective metal can be effectively performed in the long-wavelength pixel (first pixel) in which the effect of providing the reflective metal is large, and the effect of the potential due to the reflective metal on the short-wavelength pixel (second pixel) can be reduced.

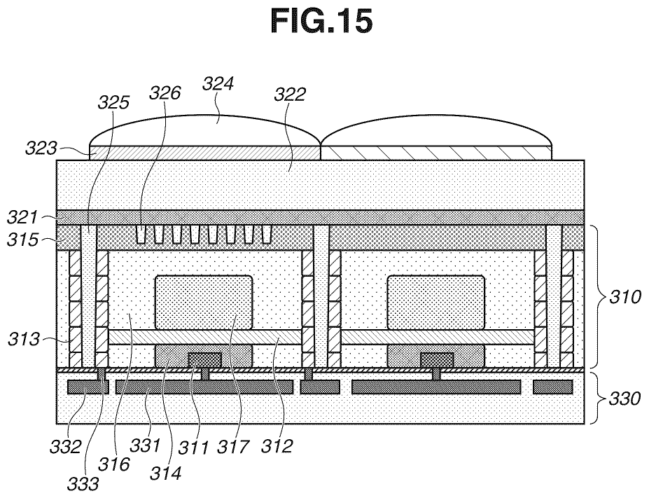

FIG. 15 is a schematic view illustrating an example of pixels 101 according to a ninth exemplary embodiment. Descriptions of components similar to those of the first exemplary embodiment illustrated in FIG. 7 will be omitted.

While the exemplary embodiments described above illustrate examples of the structure in which the optical path length is increased by providing the diffractive region 326, the increase in the optical path length may increase the possibility of occurrence of crosstalk between the pixels 101.

In the pixels 101 illustrated in FIG. 15, a connecting portion 333 between the third semiconductor region 313 and the anode wire 332 has a shape surrounding the second semiconductor region 312 in a planar view. As illustrated in FIG. 15, this structure may be provided in the long-wavelength pixel (first pixel) to reduce light with a long wavelength that is a main cause of crosstalk, but may alternatively be provided in the short-wavelength pixel (second pixel).

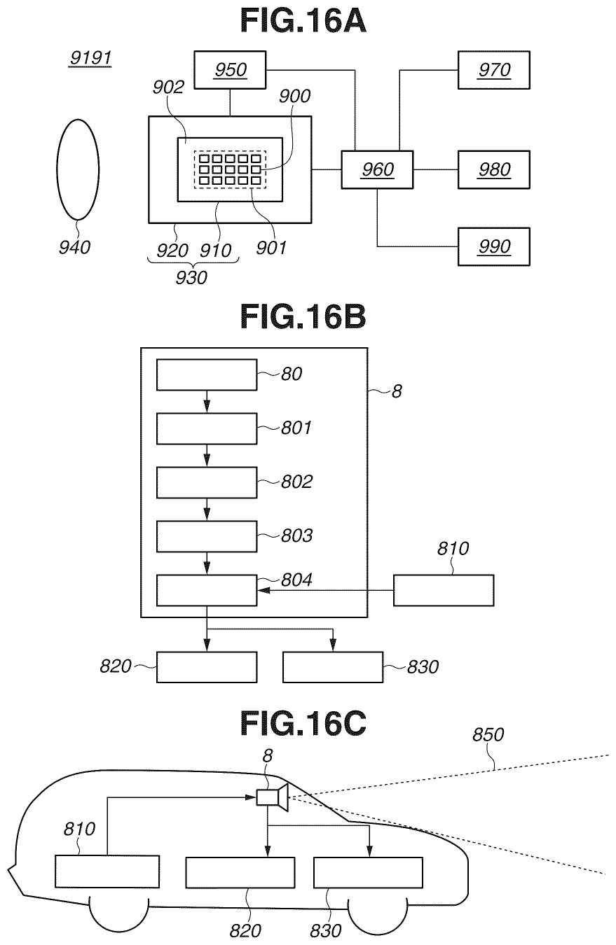

Any of the first to ninth exemplary embodiments can be applied to a tenth exemplary embodiment. FIG. 16A is a schematic diagram illustrating an apparatus 9191 including a semiconductor device 930 according to the tenth exemplary embodiment. The semiconductor device 930 can use any one of the photoelectric conversion devices (image capturing devices) according to the exemplary embodiments described above.

The apparatus 9191 including the semiconductor device 930 will be described in detail. As described above, the semiconductor device 930 may include not only a semiconductor device 910 including a semiconductor layer 902, but also a package 920 that accommodates the semiconductor device 910. The package 920 may include a base to which the semiconductor device 910 is fixed, and a lid that is made of glass or the like and is opposed to the semiconductor device 910. The package 920 may also include a joining member, such as a bonding wire or a bump, for connecting a terminal provided on the base with a terminal provided on the semiconductor device 910.

The apparatus 9191 can include at least one of an optical device 940, a control device 950, a processing device 960, a display device 970, a storage device 980, and a mechanical device 990. The optical device 940 corresponds to the semiconductor device 930. Examples of the optical device 940 include a lens, a shutter, and a mirror. The control device 950 controls the semiconductor device 930. The control device 950 is a semiconductor device, such as an application-specific integrated circuit (ASIC).

The processing device 960 processes signals output from the semiconductor device 930. The processing device 960 is a semiconductor device, such as a central processing unit (CAPU) or an ASIC, for forming an analog front end (AFE) or a digital front end (DFE). The display device 970 is an electroluminescence (EL) display device or a liquid crystal display device that displays information (images) obtained by the semiconductor device 930. The storage device 980 is a magnetic device or a semiconductor device that stores information (images) obtained by the semiconductor device 930. The storage device 980 is a volatile memory, such as a static random access memory (SRAM) or a dynamic RAM (DRAM), or a nonvolatile memory, such as a flash memory or a hard disk drive.

The mechanical device 990 includes a movable portion or a propulsive portion, such as a motor or an engine. The apparatus 9191 displays signals output from the semiconductor device 930 on the display device 970 and transmits the signals to the outside by using a transmission device (not illustrated) included in the apparatus 9191. Thus, the apparatus 9191 may also include the storage device 980 and the processing device 960 separately from a storage circuit and an arithmetic circuit that are included in the semiconductor device 930. The mechanical device 990 may be controlled based on a signal output from the semiconductor device 930.

The apparatus 9191 is suitable for an electronic apparatus, such as an information terminal (e.g., smartphone, wearable terminal) including an image capturing function, or a camera (e.g., lens-interchangeable camera, compact camera, video camera, and monitoring camera). The mechanical device 990 in a camera can drive the components of the optical device 940 for zooming, focusing, and shutter operations. Alternatively, the mechanical device 990 can move the semiconductor device 930 for an image stabilization operation.

The apparatus 9191 can be a transport apparatus, such as a vehicle, a ship, or a flight vehicle. The mechanical device 990 in the transport apparatus may be used as a moving device. The apparatus 9191 serving as a transport apparatus is suitable for transporting the semiconductor device 930 or assisting and/or automating driving (controlling) using the image capturing function. The processing device 960 for assisting and/or automating driving (controlling) can perform processing for operating the mechanical device 990 serving as a moving device based on information obtained by the semiconductor device 930. Other examples of the apparatus 9191 may include medical equipment, such as an endoscope, a measurement apparatus, such as a range sensor, analytical equipment, such as an electron microscope, business equipment, such as a copying machine, and industrial equipment, such as a robot.

According to the above-described exemplary embodiments, favorable pixel characteristics can be obtained. This enhances the value of the semiconductor device 930. Enhancing the value herein includes at least one of adding functions, improving the performance, improving the characteristics, improving the reliability, improving the production yield, reducing the environment load, reducing the cost, reducing the size, and reducing the weight.

The value of the apparatus can therefore be increased by using the semiconductor device 930 according to the present exemplary embodiment for the apparatus 9191. For example, an excellent performance can be obtained in image capturing of an outside of a transport apparatus or measurement of an external environment by incorporating the semiconductor device 930 in a transport apparatus. Thus, it is advantageous in increasing the performance of the transport apparatus itself to incorporate the semiconductor device 930 according to the present exemplary embodiment in the transport apparatus in a case of manufacturing or selling the transport apparatus. In particular, the semiconductor device 930 can be suitable for transport apparatuses that perform drive assistance and/or automated driving by using information obtained by the semiconductor device 930.

A photoelectric conversion system and a moving body according to the tenth exemplary embodiment will now be described with reference to FIGS. 16B and 16C.

FIG. 16B illustrates an example of a photoelectric conversion system for an on-vehicle camera. A photoelectric conversion system 8 includes a photoelectric conversion device 80. The photoelectric conversion device 80 is any one of the photoelectric conversion devices (image capturing devices) according to the exemplary embodiments described above. The photoelectric conversion system 8 also includes an image processing unit 801 and a parallax acquisition unit 802. The image processing unit 801 performs image processing on a plurality of pieces of image data acquired by the photoelectric conversion device 80. The parallax acquisition unit 802 calculates a parallax (phase difference between parallax images) based on the plurality of pieces of image data acquired by the photoelectric conversion system 8.

The photoelectric conversion system 8 further includes a distance acquisition unit 803 that calculates a distance to a target object based on the calculated parallax, and a collision determination unit 804 that determines whether there is a possibility of collision based on the calculated distance. The parallax acquisition unit 802 and the distance acquisition unit 803 are examples of a distance information acquisition unit that acquires distance information indicating a distance to a target object. Specifically, the distance information indicates information about a parallax, a defocus amount, a distance to a target object, and the like. The collision determination unit 804 may determine the possibility of collision using any one of the pieces of distance information.

The distance information acquisition unit may be implemented by an exclusively designed hardware or software module. Alternatively, the distance information acquisition unit may be implemented by a field-programmable gate array (FPGA), an ASIC, or the like, or a combination thereof.

The photoelectric conversion system 8 is connected to a vehicle information acquisition device 810, and is configured to acquire vehicle information, such as a vehicle speed, a yaw rate, and a steering angle. The photoelectric conversion system 8 is also connected to an engine control unit (ECU) 820 serving as a control device that outputs a control signal for generating a braking force for a vehicle based on the determination result from the collision determination unit 804. The photoelectric conversion system 8 is also connected to an alarm device 830 that issues an alarm to a driver based on the determination result from the collision determination unit 804.

For example, if there is a high possibility of collision based on the determination result from the collision determination unit 804, the ECU 820 performs a vehicle control operation to avoid a collision or reduce damage by, for example, applying brakes, releasing an accelerator, or restraining engine power. The alarm device 830 issues a warning to a user by, for example, generating an alarm sound, displaying warning information on a screen of a car navigation system, or applying vibrations to a seat belt or a steering wheel.

In the present exemplary embodiment, the photoelectric conversion system 8 captures images of an area around the vehicle, such as the front side or the rear side of the vehicle. FIG. 16C illustrates an example of the photoelectric conversion system 8 in a case where an image of the front side of the vehicle (imaging range 850) is captured. The vehicle information acquisition device 810 sends an instruction to the photoelectric conversion system 8 or the photoelectric conversion device 80. This configuration can further improve the accuracy of ranging.

While an example of the control operation for avoiding a collision with another vehicle is described above, the present exemplary embodiment is also applicable to a control operation for automated driving to follow another vehicle, a control operation for automated driving not to stray from a traffic lane, and the like. The photoelectric conversion system 8 is not limited to a vehicle such as an automobile, and is also applicable to, for example, a moving body (traveling apparatus), such as a ship, an airplane, or an industrial robot. For example, the photoelectric conversion system 8 may include a moving body including any one of the photoelectric conversion devices described in the exemplary embodiments and a control unit that controls a movement of the moving body using a signal output from the photoelectric conversion device. The photoelectric conversion system 8 is applicable not only to a moving body, but also to an apparatus that widely uses object recognition, such as an intelligent transport system (ITS). The above-described exemplary embodiments are merely specific examples for carrying out the present disclosure. The technical scope of the present disclosure should not be interpreted in a limited way. That is, the present disclosure can be carried out in various forms without departing from the technical idea or the main features thereof. For example, any combination of elements in the exemplary embodiments described above is also within the present disclosure.

The exemplary embodiments described above can be changed, as needed, without departing from the technical idea. The disclosed contents of the specification of the present disclosure include not only the contents described herein, but also all matters that can be understood from the specification and drawings attached to the specification.

According to at least one of the exemplary embodiments of the present disclosure, it is possible to provide a photoelectric conversion device in which sensitivity to incident light is improved while adverse effects on the performance of the photoelectric conversion device is reduced.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2023-168618, filed Sep. 28, 2023, which is hereby incorporated by reference herein in its entirety.

What is claimed is:

1. A device comprising:
a plurality of pixels each including an avalanche photodiode,
wherein the plurality of pixels includes a first pixel, and a second pixel configured to photoelectrically convert incident light including light with a wavelength shorter than a wavelength of incident light to be photoelectrically converted by the first pixel,
wherein the avalanche photodiode is provided in a semiconductor layer, and
wherein the semiconductor layer of the first pixel is provided with a first diffractive region configured to diffract incident light, and the second pixel is not provided with the first diffractive region.

2. The device according to claim 1, wherein the first diffractive region includes a first recessed portion including a plurality of recessed portions formed on a first surface as a light incidence surface of the semiconductor layer provided with the avalanche photodiode.

3. The device according to claim 2,
wherein the second pixel includes an anti-reflection region including a second recessed portion including a plurality of recessed portions configured to reduce reflection of incident light, and
wherein an interval between the plurality of recessed portions in the second recessed portion is smaller than an interval between the plurality of recessed portions in the first recessed portion.

4. The device according to claim 1, further comprising a wiring layer on a second surface opposed to a first surface which is a light incidence surface of the semiconductor layer provided with the avalanche photodiode.

5. The device according to claim 4,
wherein the wiring layer includes a reflective metal configured to reflect incident light, and
wherein, in a planar view, an area of the reflective metal overlapping the first pixel is larger than an area of the reflective metal overlapping the second pixel.

6. The device according to claim 4,
wherein the semiconductor layer provided with the avalanche photodiode includes a semiconductor region between the plurality of pixels, and
wherein, in the first pixel, a connecting portion to connect the semiconductor region to a wire provided in the wiring layer is provided to surround the avalanche photodiode in a planar view.

7. The device according to claim 2, wherein an interval between the plurality of recessed portions included in the first recessed portion in a central portion of the first pixel is different from the interval between the plurality of recessed portions included in the first recessed portion in a peripheral portion of the first pixel.

8. The device according to claim 7, wherein the interval between the plurality of recessed portions included in the first recessed portion in a central portion of the first pixel is smaller than the interval between the plurality of recessed portions included in the first recessed portion in a peripheral portion of the first pixel.

9. The device according to claim 7, wherein the interval between the plurality of recessed portions included in the first recessed portion in a central portion of the first pixel is larger than the interval between the plurality of recessed portions included in the first recessed portion in a peripheral portion of the first pixel.

10. The device according to claim 2, further comprising a second diffractive region, the second diffractive region being provided on a second surface opposed to the first surface,
wherein the first pixel is provided with the second diffractive region in a planar view and the second pixel is not provided with the second diffractive region.

11. The device according to claim 1, wherein the second pixel is provided with an anti-reflection region to reduce reflection of incident light on a first surface as a light incidence surface of the semiconductor layer provided with the avalanche photodiode.

12. The device according to claim 2, wherein the plurality of recessed portions included in the first recessed portion has a trench structure.

13. The device according to claim 2, wherein the plurality of recessed portions included in the first recessed portion each has a quadrangular pyramid shape.

14. The device according to claim 2, wherein the plurality of recessed portions included in the first recessed portion is each provided with an insulating material.

15. The device according to claim 2, wherein the plurality of recessed portions included in the first recessed portion is each provided with a metal.

16. The device according to claim 1, wherein a wavelength of peak sensitivity of the first pixel is near-infrared light.

17. The device according to claim 1, wherein a wavelength of peak sensitivity of the second pixel is visible light.

18. A device comprising:
a plurality of pixels each including an avalanche photodiode; and
a wiring layer provided on a second surface opposed to a first surface as a light incidence surface of a semiconductor layer provided with the avalanche photodiode,
wherein the plurality of pixels includes a first pixel, and a second pixel configured to photoelectrically convert incident light including light with a wavelength shorter than a wavelength of incident light to be photoelectrically converted by the first pixel,
wherein the wiring layer includes a reflective metal to reflect incident light, and
wherein, in a planar view, an area of the reflective metal overlapping the first pixel is larger than an area of the reflective metal overlapping the second pixel.

19. A device comprising:
a plurality of pixels each including an avalanche photodiode; and
an anti-reflection region configured to reduce reflection of incident light, the anti-reflection region being provided on a first surface as a light incidence surface of a semiconductor layer provided with the avalanche photodiode,
wherein the plurality of pixels includes a first pixel, and a second pixel configured to photoelectrically convert incident light including light with a wavelength shorter than a wavelength of incident light to be photoelectrically converted by the first pixel, and
wherein the first pixel is provided with the anti-reflection region and the second pixel is not provided with the anti-reflection region.

20. A device comprising:
a plurality of pixels each including a photoelectric conversion element,
wherein the plurality of pixels includes a first pixel, and a second pixel configured to photoelectrically convert incident light including light with a wavelength shorter than a wavelength of incident light to be photoelectrically converted by the first pixel, and
wherein the first pixel is provided with a diffractive region configured to diffract incident light and the second pixel is not provided with the diffractive region.

21. An apparatus comprising:
the device according to claim 1,
wherein the apparatus further comprises at least one of
an optical device compatible with the device,
a control device configured to control the device,
a processing device configured to process a signal output from the device,
a display device configured to display information obtained by the device,
a storage device configured to store information obtained by the device, and
a mechanical device configured to operate based on information obtained by the device.

22. A moving body comprising:
the device according to claim 1; and
a control unit configured to control a movement of the moving body by using a signal output from the device.
